(19) United States
(12) Patent Application Publication
(10) Pub. No.: US 2018/0204993 A1
(43) Pub. Date: Jul. 19, 2018

(54) HEAT-CONDUCTIVE AND ELECTRICALLY INSULATING CONNECTION FOR A THERMOELECTRIC MODULE

(71) Applicant: Mahle International GmbH, Stuttgart (DE)

(72) Inventors: Thomas Himmer, Reichenbach (DE); Christopher Laemmle, Stuttgart (DE)

(21) Appl. No.: 15/552,097

(22) PCT Filed: Jan. 22, 2016
(86) PCT No.: PCT/EP2016/051343

§ 371 Date: Aug. 18, 2017

(30) Foreign Application Priority Data
Feb. 19, 2015 (DE) 10 2015 202 968.9

(51) Int. Cl. H01L 35/30; H01L 35/32; H01L 35/34

(52) U.S. Cl. CPC H01L 35/30; H01L 35/34; H01L 35/32

(57) ABSTRACT

A heat-conductive and electrically insulating connection for securing a thermoelectric element to an outer wall, e.g., a hot side and/or a cold side, of a thermoelectric module may include an electrical insulation layer connected to the outer wall. The insulation layer may be provided by a dielectric. The connection may also include an electrically conductive metal layer connected to the insulation layer. The thermoelectric element may be connected in an electrically conductive and fixed manner to the metal layer acting as a conductor bridge. Additionally or alternatively, the thermoelectric element may be connected in an electrically conductive and fixed manner to a separate conductor bridge.

### CROSS-REFERENCE TO RELATED APPLICATIONS

This application claims priority to German Patent Application No. 10 2015 202 968.9 filed on Feb. 19, 2015, and International Patent Application No. PCT/EP2016/051343, filed on Jan. 22, 2016 the contents of which are hereby incorporated by reference in their entirety.

### TECHNICAL FIELD

The present invention relates to a heat-conductive and electrically insulating connection for fastening a thermoelectric element to an outer wall, which forms a cold side or a hot side of a thermoelectric module, which has a plurality of such thermoelectric elements in a module inner space. The invention also relates to a thermoelectric module, in which at least one thermoelectric element is fastened by means of such a connection at least on an outer wall of the thermoelectric module. Finally, the present invention relates to a method for producing such a connection or respectively such a thermoelectric module.

### BACKGROUND

A thermoelectric module comprises a plurality of thermoelectric elements in the form of positively and negatively doped thermoelectrical semiconductor materials, which are electrically interconnected via a plurality of conductor bridges. The thermoelectric module has on its cold side an outer wall which can be designated as cold side wall, and which is connected with a plurality of cold-side conductor bridges in a heat-conductive, electrically insulated and fixed manner. In an analogous manner thereto, the thermoelectric module comprises on its warm side an outer wall, which forms a warm side wall, which is connected to a plurality of warm-side conductor bridges in a heat-conductive, electrically insulated and fixed manner. The thermoelectric elements are arranged here between the cold side wall and warm side wall, so that they extend between the cold-side and warm-side conductor bridges.

Such a thermoelectric module is known for example from DE 15 39 322 A1.

Such thermoelectric modules come into use in order to convert temperature differences into an electrical potential difference, therefore into an electrical voltage. Hereby, a flow of heat can be converted into an electric current. The so-called Seebeck effect is used here, which corresponds to a reversal of the so-called Peltier effect. For example, such thermoelectric modules can be used for waste heat utilization, for example in an internal combustion engine. Excess waste heat, e.g. in the exhaust gas, has for example a temperature difference with respect to an environment or with respect to a coolant, whereby a heat flow can be produced, which can be converted by means of such thermoelectric modules into an electric current which corresponds to said waste heat utilization.

In thermoelectric modules, the different coefficients of thermal expansion of the individual components, arranged therein and connected to one another, are a problem. In addition to this is a high frequency of load alternations with regard to the temperatures occurring in vehicle applications. In addition, a permanent fixed connection on the one hand between the thermoelectric elements and the conductor bridges, and on the other hand between the conductor bridges and the respective outer wall is crucial for a high efficiency of such a thermoelectric module, in order to achieve a good heat flow inside the thermoelectric module. Metallic materials preferably come into use here, because these are distinguished by a high thermal conductivity. Accordingly, the outer walls, the conductor bridges and the thermoelectric elements consist of metallic materials. To prevent a short-circuit inside the thermoelectric module, however, it is necessary to provide an electrical insulation between the outer walls and the conductor bridges. Conflicting requirements are now placed on such an electrical insulation. On the one hand, it must electrically insulate efficiently, whereas on the other hand it is to possess a good thermal conductivity. At the same time, it must be able to be connected fixedly and permanently to the respective outer wall and to the respective conductor bridge.

### SUMMARY

The present invention is concerned with the problem of indicating for a thermoelectric module a way for a permanent heat-conductive and electrically insulating connection between an outer wall and a thermoelectric element. In addition, a possibility is to be indicated for producing such a connection or respectively such a thermoelectric module at a favourable cost.

This problem is solved according to the invention by the subjects of the independent claims. Advantageous embodiments are the subject of the dependent claims.

The invention is based on the general idea of configuring the heat-conductive and electrically insulating connection by means of an electrically insulating insulation layer formed by a dielectric, and by means of an electrically conductive metal layer, wherein the insulation layer is fixedly connected to the respective outer wall, whilst the metal layer is fixedly connected to the insulation layer. In addition, in a first case, the metal layer is fixedly connected to a conductor bridge, which in turn is fixedly connected to at least one thermoelectric element. In a second case, in contrast, the metal layer is embodied so that it itself acts as a conductor bridge, and accordingly is connected directly to at least one thermoelectric element.

The dielectric is, by definition, metal-free and forms an efficient electrical insulator. Such a dielectric insulation layer can be applied fixedly on the respective metallic outer wall. In addition, the said metal layer can be fixedly arranged on the insulation layer, which in turn is suited for fastening the conductor bridges or the thermoelectric elements thereon. Therefore, a structure is produced for the thermoelectric module, in which a comparatively permanent, fixed connection can be created between the thermoelectric elements and the respective outer wall, which is distinguished by an efficient electrical insulation effect and by a relatively favourable heat conduction. Furthermore, coatings can be configured regularly in a manner suitable for series production, so that an economically priced production of the thermoelectric modules is possible.

According to an advantageous embodiment, the electrical insulation layer is formed by a dielectric stoving paste, which is applied onto the respective outer wall and stoved during the production of the connection. The “stoving” here is a thermal method, in which the stoving paste is heated to a temperature at which components of the stoving paste liquefy, whilst the respective outer wall remains largely solid. The liquefied components of the stoving paste can penetrate into surface roughnesses of the outer wall or respectively integrate these into the insulation layer, whereby after the solidifying of the stoving paste after the stoving process, a permanent, thermally hard-wearing fixed connection forms between the insulation layer and the outer wall. Depending on the material composition of the stoving paste and the outer wall, basically also fusion connections or fusion-like connections can be generated, which makes possible a materially bonded or material bond-like connection between insulation layer and outer wall. It is particularly advantageous here that such a stoving paste can be used particularly simply in the context of a mass production. For example, such a stoving paste can be printed onto the outer wall, for example by a screen printing method. A dielectric stoving paste contains, in addition to the fusing components, also solid particles, which do not fuse during the stoving. These solid particles consist of an electrically insulating material. Non-metallic solid particles are preferably concerned here, such as e.g. ceramic particles and/or glass particles.

Basically, the electrically conductive metal layer can be formed by a metallization of the insulation layer. Such a metallization can be realized for example by different methods of thin film technology, by way of example by a physical vapour deposition process, for example by a so-called sputter deposition or by a thermal vaporization. In addition, a physical or chemical vapour deposition process can be realized, so-called PVD or CVP processes, for example a plasma-assisted chemical vapour deposition. Furthermore, it is conceivable to realize the metallization by a thermal spraying or by a galvanizing.

However, an embodiment is preferred, in which the electrically conductive metal layer is formed by a metallic stoving paste. Such a metallic stoving paste contains, alongside the components which fuse during the stoving process, in addition solid particles, preferably metal particles, which do not fuse during the storing and which provide for the electrical conductivity of the metal layer. Here, also, the stoving of the stoving paste provides for a particularly fixed and permanent connection of the metal layer to the insulation layer. By a corresponding complementary choice of the components or respectively constituents, which liquefy in the respective stoving paste, a particularly fixed connection can be achieved between the metal layer and the insulation layer. Particularly advantageously, the fusing materials can be coordinated with one another so that a fusion connection occurs between the metal layer and the insulation layer, therefore a materially bonded connection. In so far as both the insulation layer is realized by means of a dielectric stoving paste and also the metal layer is realized by means of a metallic stoving paste, it is conceivable to coordinate the components liquefying in the pastes with one another so that they fuse with one another during the stoving of the metal layer, therefore combine with one another in a materially bonded manner or respectively chemically. Hereby, the high-strength connection which is thus generated becomes particularly insensitive with respect to alternating thermal loads.

An embodiment is preferred, in which the electrical insulation layer has a layer thickness of at least 20 μm. The electrical insulation layer can be designed here basically as a single-layered insulation layer. However, an embodiment is preferred, in which the electrical insulation layer is designed having multiple layers. For example, it is conceivable that the insulation layer is built up from two to four layers of the insulation material. Preferably, the layer thickness of the insulation layer then lies in a range of inclusively 40 μm to inclusively 120 μm. An embodiment is particularly advantageous, in which the layer thickness of the insulation layer lies in a range of approximately 50 μm to approximately 100 μm.

Additionally or alternatively, provision can be made that the electrically conductive metal layer has a layer thickness of at least 5 μm. Here, also, it is conceivable to embody the metal layer so as to be single-layered. However, a multi-layered structure of the metal layer is preferred. In so far as the metal layer serves only for creating a metallic connection surface on the insulation layer, which leads to the fixed connecting with a separate conductor bridge, a layer thickness of 10 μm to 20 μm can be sufficient here. If, in contrast, the metal layer itself is to be used as an electrically conductive conductor bridge, a layer thickness of 150 μm to 300 μm is advantageous. In so far as a multi-layered coating is provided for the insulation layer or the metal layer, this can be realized in that the respective stoving paste is applied accordingly in a multi-layered manner, wherein expediently after each application firstly a stoving process is carried out, until the next layer is applied.

According to another embodiment, the dielectric can be formed by a polymer-based or by a glass-based system with non-metallic solid particles, such as e.g. ceramic particles and/or glass particles. Hereby, on the one hand a particularly efficient mechanical connection to the metallic outer wall can be realized, whilst at the same time a sufficient electrical insulation can be produced. The polymer basis or respectively the glass basis forms here the fusing component of the dielectric stoving paste.

To improve the adhesion of the insulation layer to the outer wall, it can be expedient to roughen the outer wall accordingly, which can be realized by mechanical processing and/or by a chemical processing.

In another embodiment, the metal layer can be formed by a polymer-based or glass-based system with metal particles. Therefore, the metal layer has a high compatibility to the above-mentioned dielectric, which enables an efficient and permanent connection between the metal layer and the insulation layer.

According to another advantageous embodiment, for the case where a separate conductor bridge is used, provision can be made that the conductor bridge has a bridge body of a metal alloy of copper base or silver base or nickel base. Such a conductor bridge can be connected particularly simply in a fixed and permanent manner to the metal layer, wherein at the same time a high thermal conductivity and a high electrical conductivity are achieved.

A further development is advantageous, in which the bridge body, produced from a metal alloy of copper base or nickel base is provided on a side facing the metal layer, but preferably on its entire outer side, with a coating of silver base and/or nickel base. Hereby, the bridge body can be connected particularly simply in a fixed and permanent manner to the metal layer, for example by a soldering method.

In another embodiment, provision can be made that the respective thermoelectric element has an element body of a thermoelectrically active material. Depending on the position of the thermoelectric element, this concerns either a positively doped or a negatively doped semiconductor material. Such thermoelectrically active materials are basically known. An embodiment is particularly advantageous in which the element body is provided with a metal coating at least in the region of the conductor bridge. Hereby, the respective thermoelectric element can be connected particularly simply with high strength to the respective conductor bridge, which—as illustrated several times—can be realized either by a separate component or by a metal layer embodied so as to be correspondingly thick. For example, the metal coating of the element body can be formed from an alloy of titanium base or of nickel base or of nickel-boron base or of silver base.

In another advantageous embodiment, the thermoelectric element can be connected to the separate conductor bridge or to the metal layer serving as conductor bridge in a materially bonded manner by means of silver sintering or brazing or soft-soldering. Sintering methods and soldering methods are suitable in particular for a mass production. The materially bonded connections which are thereby achievable are distinguished by a high fatigue strength.

According to another embodiment, the outer wall can be segmented by means of at least one gap, wherein a metal foil, arranged on the outer side of the outer wall, and/or a jointing material tightly closing the respective gap can be provided. The segmenting of the outer wall leads to a mechanical decoupling of the individual segments of the outer wall, so that the individual segments of the outer wall can move relative to one another, which can be necessary for example in the context of a thermally caused expansion. At the same time, through the segmenting of the outer wall, it is achieved that the conductor bridges or respectively thermoelectric elements fastened thereon are likewise decoupled from one another according to the segmenting of the outer wall, so that they likewise are movable relative to one another. This provision also improves the thermal stability of the thermoelectric module.

A thermoelectric module according to the invention is distinguished by two outer walls which delimit a module inner space and one outer wall of which forms a cold side of the thermoelectric module, whereas the other outer wall forms a hot side of the thermoelectric module. In the module inner space, the thermoelectric module has a plurality of thermoelectric elements which are electrically interconnected by means of conductor bridges. Here, at least one such thermoelectric element is fastened to at least one of these outer walls by means of a heat-conductive and electrically insulating connection of the type described above. Expediently, all thermoelectric elements are fastened to at least one of the outer walls by means of such a connection. Furthermore, provision is preferably made that the respective thermoelectric element is fastened to both outer walls respectively by means of such a connection. An embodiment is therefore particularly advantageous in which all thermoelectric elements of the thermoelectric module are fixedly connected by means of such connections of the type described above on the one hand to the one outer wall forming the cold side and on the other hand to the other outer wall forming the hot side. As mentioned several times, the conductor bridges provided here are either integrated in the form of separate components into the respective connection or are realized by a correspondingly thick metal layer within the respective connection.

Such a thermoelectric module can basically be realized in the form of a separate component such that the two outer walls are connected securely and tightly to one another along a circumferential edge, whereby the module inner space is hermetically sealed. The module inner space can be expediently evacuated here or can be filled with an inert gas. Such hermetically encapsulated thermoelectric modules can then be installed particularly simply for example into a heat exchanger, via which a heat source is thermally coupled to a heat sink. For example, such a heat exchanger contains heating pipes, through which a heating path is directed for guiding an exothermic heating medium, and cooling pipes, through which a cooling path is directed for guiding an endothermic cooling medium. The respective thermoelectric module can now be arranged in a suitable manner between such a heating pipe and such a cooling pipe, for example so that an outer side of the heating pipe touches the outer wall forming the hot side of the thermoelectric module, whilst an outer side of the cooling pipe touches the outer wall forming the cold side of the thermoelectric module. This touching takes place preferably directly, but can also take place indirectly via a thermally conductive paste and suchlike. In addition, an embodiment for such a heat exchanger is conceivable, in which such a heating pipe and/or such a cooling pipe has a recess into which the thermoelectric module is inserted, such that the outer wall forming the hot side of the thermoelectric module forms an integrated portion of the heating pipe, so that the outer wall, during operation of the heat exchanger, is acted upon directly by the exothermic heating medium. Additionally or alternatively, the thermoelectric module can be inserted with its outer wall forming the cold side into such a cooling pipe, such that this outer wall forms a portion of the cooling pipe, so that the outer wall of the thermoelectric module during operation of the heat exchanger is acted upon directly by the endothermic cooling medium.

A method according to the invention for producing a connection of the type described above, which can also be used, accordingly modified, for producing such a thermoelectric module, is distinguished in that firstly an electrically insulating insulation layer is produced, by a dielectric stoving paste being applied onto the respective outer wall of the thermoelectric module and stoved. This can be realized for example by means of a screen printing method. This can be repeated several times, in order to produce a multi-layered insulation layer. Optionally, for the method, provision can be made to produce an electrically conductive metal layer, by a metallic stoving paste being applied onto the insulation layer and stoved. This can also be realized for example by means of a screen printing method. In particular, this process can also be carried out several times in succession, in order to produce a multi-layered metal layer. Furthermore, provision can optionally be made to connect at least one thermoelectric element either directly to the metal layer, which then serves as conductor bridge, or indirectly via a separate conductor bridge, to the metal layer by means of a sintering process or soldering process. Here, also, for the connection of the thermoelectric element to the conductor bridge a thermal method is used. When a separate conductor bridge is used, the latter is likewise connected to the metal layer by means of a sintering process or a soldering process, whilst at the same time the respective thermoelectric element is connected to the conductor bridge by means of the same sintering process or respectively soldering process. Therefore, only one sintering process or soldering process is necessary in order to connect the respective separate conductor bridge on the one hand to the metal layer and on the other hand to the respective thermoelectric element.

Further important features and advantages of the invention will emerge from the subclaims, from the drawings and from the associated FIGURE description with the aid of the drawings.

It shall be understood that the features mentioned above and to be explained further below are able to be used not only in the respectively indicated combination, but also in other combinations or in isolation, without departing from the scope of the present invention.

Preferred example embodiments of the invention are illustrated in the drawings and are explained in further detail in the following description.

### BRIEF DESCRIPTION OF THE DRAWINGS

The FIGURE shows a cross-section through a part of a thermoelectric module.

### DETAILED DESCRIPTION

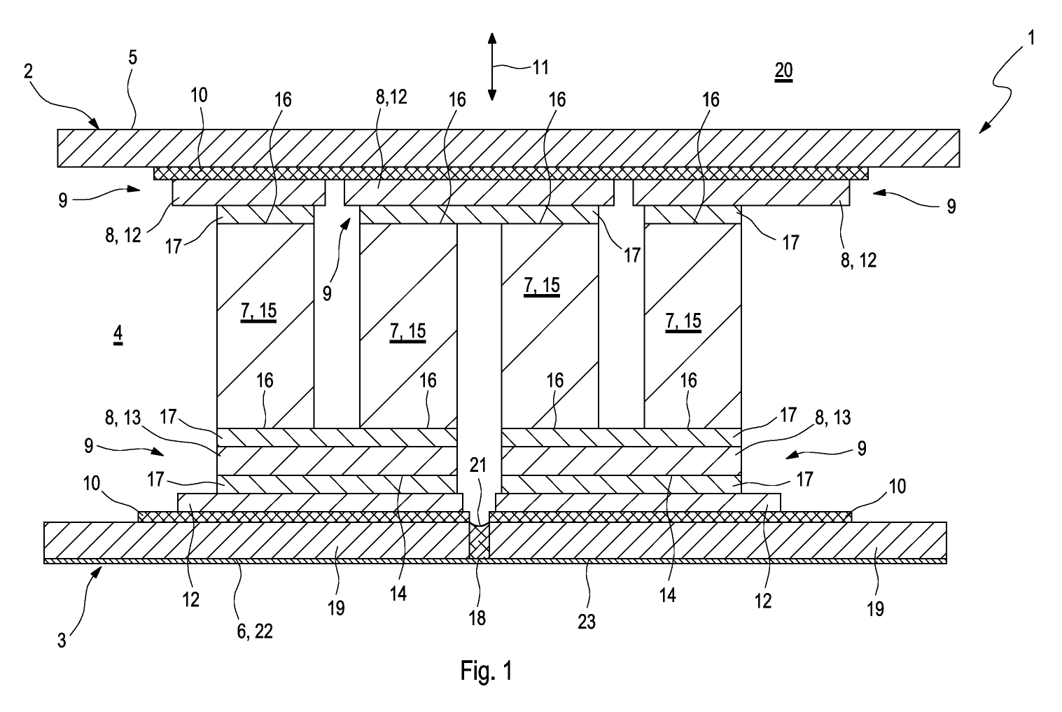

According to FIG. 1, a thermoelectric module 1, which is illustrated only partially here, comprises two outer walls 2, 3, which delimit a module inner space 4. One outer wall 2, for example the outer wall 2 shown at the top in FIG. 1, forms a cold side 5 of the thermoelectric module 1. The opposite, other outer wall 3, in the example the outer wall 3 shown at the bottom in FIG. 1, forms a hot side 6 of the thermoelectric module 1.

The thermoelectric module 1 has in addition a plurality of thermoelectric elements 7, which are arranged in the module inner space 4 and are electrically interconnected by means of conductor bridges 8. The thermoelectric elements 7 are fixedly connected here to the two outer walls 2, 3 respectively by means of an electrically insulating and heat-conductive connection 9, which contains the respective conductor bridge 8. Preferably, these connections 9 can be configured identically for both outer walls 2, 3. In FIG. 1, however, an example is reproduced for illustration, in which the connections 9 to the outer wall 2 shown at the top are configured differently from with the outer wall 3 shown at the bottom. The two connection types differ by the manner in which the conductor bridge 8, arranged therein, is realized, which is described more precisely further below.

The respective connection 9 serves for fastening such a thermoelectric element 7 to such an outer wall 2, 3. For this, the respective connection 9 comprises an electrical insulation layer 10, which is fixedly connected to the respective outer wall 2, 3. The insulation layer 10 is formed here by a dielectric. Preferably, the insulation layer 10 is formed by a dielectric stoving paste, which has been applied onto the respective outer wall 2, 3 and stoved in the context of the production of the respective connection 9. For example, the dielectric is formed by a polymer-based or glass-based system with ceramic particles. Preferably, the insulation layer 10 is realized with a layer thickness of at least 20 μm in a thickness direction 11 of the thermoelectric module 1, which is indicated in FIG. 1 by a double arrow. The layer thickness of the insulation layer 10 can lie for example in a range of 40 to 120 μm. A layer thickness of 75 to 100 μm is preferred. In so far as the insulation layer 10 is designed having multiple layers, the individual layer has a layer thickness of approximately 25 μm, wherein deviations of a maximum of 5 μm in one and in the other direction are permissible.

The thickness direction 11 extends perpendicularly to the outer walls 2, 3, which are configured as flat sheets.

The respective connection 9 comprises in addition an electrically conductive metal layer 12, which is applied in the region of the respective conductor bridge 8 onto the insulation layer 10 and is fixedly connected therewith. Here, also, an embodiment is preferred, in which the electrically conductive metal layer 12 is formed by a metallic stoving paste, which has been applied onto the insulation layer 10 and stoved in the context of the production. Expediently, a variant is also preferred here, in which the metal layer 12 is formed by a polymer-based or glass-based system with metal particles. Here, also, a single-layered or multi-layered application of the metal layer 12 comes into consideration. A layer thickness of the metal layer 12, measured in the thickness direction 11, is at least 5 □m here. Basically, however, layer thicknesses of 10 to 30 □m are conceivable, if the metal layer 12, as in the region of the lower outer wall 3, serves for fastening a separate conductor bridge 8. Likewise, it is conceivable to realize the metal layer 12 with a greater layer thickness, for example with a layer thickness of 150 μm to 300 μm, especially when the metal layer 12, as in the region of the upper outer wall 2, is itself to serve as conductor bridge 8. Therefore, the connection types which are presented here differ from one another in that in the connection type associated with the upper outer wall 2, the conductor bridges 8 are not provided as separate elements, but rather by corresponding portions of the metal layer 12, which is embodied so as to be accordingly thick, whereas in the connection type associated with the lower outer wall 3, separate conductor bridges 8 are provided, which are fixedly connected to corresponding portions of the metal layer 12.

If a separate conductor bridge 8 is present, as in FIG. 1 at the bottom, within the respective connection 9, this conductor bridge 8 expediently has a bridge body 13, which is based for example on a metal alloy of copper base or silver base or nickel base. Advantageously, the concern is with a bridge body 13 of a metal alloy of copper base. Optionally, this bridge body 13 can be provided with a metal coating 14 at least on an outer side facing the metal layer 12 and on an outer side facing the thermoelectric elements 7, which metal coating is based for example on a silver base or on a nickel base.

The thermoelectric elements 7 have respectively an element body 15 of a thermoelectrically active material. This can concern positively doped and negatively doped semiconductor materials, which are interconnected accordingly by means of the conductor bridges 8. In order to improve the connection of the thermoelectric elements 7 to the conductor bridges 8, the element bodies 15 can be provided with a metal coating 16 at least in the region of the respective conductor bridge 8. Such a metal coating 16 can be based on a titanium base or nickel base or nickel-boron base or silver base.

For fastening the individual thermoelectric elements 7 to the respective conductor bridge 8, a sintering method or a soldering method can be used. Corresponding sinter layers or solder layers are designated here by 17 in FIG. 1. The respective sinter layer 17 or solder layer 17 can be produced here by a silver sintering or by a brazing, which takes place with soldering temperatures above 450° C., of by a soft soldering, which takes place at a soldering temperature below 450° C. In any case, the respective sinter layer 17 or solder layer 17 produces a materially bonded connection between the thermoelectric element 7 and the respective conductor bridge 8. In so far as, as in FIG. 1 in the case of the upper outer wall 2 the conductor bridge 8 is realized by a correspondingly thick metal layer 12, only one sinter layer 17 or respectively solder layer 17 is necessary in order to connect the thermoelectric element 7 directly to the metal layer 12. If, on the contrary, as in FIG. 1 in the case of the lower outer wall 3, a separate conductor bridge 8 is provided, expediently two such sinter layers 17 or respectively solder layers 17 come into use, namely in order to connect the respective separate conductor bridge 8 on the one hand to the thermoelectric elements 7 and on the other hand to the metal layer 12.

In FIG. 1 purely by way of example only for the bottom outer wall 3 an optional segmenting of the outer wall 3 is reproduced, which is realized by means of at least one gap 18. In so far as such a segmenting of the outer walls 2, 3 comes into consideration, preferably, but not imperatively, both outer walls 2, 3 are segmented. The gap 18 completely penetrates the respective outer wall 3 in the thickness direction 11, whereby the outer wall 3 is divided into outer wall segments 19 which are decoupled from one another. In order to be able to nevertheless separate the module inner space 4 from an environment 20 of the thermoelectric module 1, the respective gap 18 can be closed for example by a jointing material 21. The jointing material 21 is elastic and can compensate varying gap widths which can arise through thermally caused expansion movements of the two outer wall parts 19 relative to one another. Additionally or alternatively, a metal foil 23 can be arranged on an outer side 22 of the segmented outer wall 3 facing away from the module inner space 4, which metal foil closes the respective gap 18.

To sum up, such a connection 9 or respectively a thermoelectric module 1 equipped therewith can be produced particularly simply in that firstly the insulation layer 10 is applied onto the respective outer wall 2 or respectively 3, by, for example by means of screen printing, a dielectric stoving paste being applied onto the respective outer wall 2 or respectively 3, and stoved. This procedure can be repeated several times, if a multi-layered configuration is desired for the insulation layer 10. Subsequently, the metal layer 12 can be applied, by a metallic stoving paste being applied onto the insulation layer 10 and stoved. Here, also, this procedure can be repeated several times, in order to produce, if required, a multi-layered metal layer 12. A multi-layered metal layer 12 comes into consideration in particular when the metal layer 12 is to be embodied so thick that it, itself, serves as conductor bridge 8, as shown in the example of the top outer wall 2.

After the arranging of the metal layer 12, the thermoelectric elements 8, if applicable with the separate conductor bridges 8 can be deposited in connection with a corresponding coating with sinter material or solder material and can be subsequently sintered or respectively soldered.

1. A heat-conductive and electrically insulating connection for securing a thermoelectric element in a module inner space of a thermoelectric module, comprising:
an electrical insulation layer firmly connected to an outer wall defining one of a hot side and a cold side, the electrical insulation layer provided by a dielectric;
an electrically conductive metal layer firmly connected to the electrical insulation layer;
a separate conductor bridge connected to the electrically conductive metal layer in a fixed manner and to the thermoelectric element in an electrically conductive and fixed manner for electrically connecting the thermoelectric element to at least one further thermoelectric element;
the conductor bridge having a metal alloy bridge body composed of a copper-based material or a nickel-based material;
a coating disposed on the bridge body composed of at least one of a silver base material and a nickel base material;
wherein the dielectric includes a polymer-based system or a glass-based system and non-metallic solid particles; and
wherein the outer wall is segmented by at least one gap, and wherein at least one of a metal foil is arranged on an outer side of the outer wall and a jointing material closes the at least one gap.

2. The connection according to claim 1, wherein the electrical insulation layer is provided by a dielectric stoving paste.

3. The connection according to claim 1, wherein the electrically conductive metal layer is provided by a metallic stoving paste.

4. The connection according to claim 1, wherein at least one of:
the electrical insulation layer has a layer thickness of at least 20 μm, and
the electrically conductive metal layer has a layer thickness of at least 5 μm.

5. The connection according to claim 1, wherein the metal layer is a polymer-based system or glass-based system with metal particles.

6. The connection according to claim 1, wherein an element body of the thermoelectric element is composed of a thermoelectrically active material, and wherein a metal coating is provided on the element body at least in region of the conductor bridge.

7. The connection according to claim 1, further comprising a materially bonded connection between the thermoelectric element and at least one of the separate conductor bridge and the metal layer, the materially bonded connection including a silver sintered connection, a brazed connection or a soft soldered connection.

8. A thermoelectric module, comprising:
a cold side outer walls and a hot side outer wall delimiting a module inner space;
a plurality of thermoelectric elements arranged in the module inner space;
a plurality of conductor bridges electrically interconnecting the plurality of thermoelectric elements;
a heat-conductive and electrically insulating connection fastening at least one thermoelectric element of the plurality of thermoelectric elements to at least one of the cold side outer wall and the hot side outer walls, the heat-conductive and electrically insulating connection including:
an electrical insulation dielectric layer connected to the at least one of the cold side outer wall and the hot side outer wall, the electrical insulation dielectric layer composed of a polymer-based material with non-metallic solid particles or a glass-based material with non-metallic solid particles;
an electrically conductive metal layer connected to the electrical insulation dielectric layer and at least one conductor bridge of the plurality of conductor bridges;
the at least one conductor bridge having a metal alloy bridge body composed of a copper-based material or a nickel-based material;
a coating disposed on the metal alloy bridge body and composed of at least one of a silver-based material and a nickel-based material;
wherein the at least one of the cold side outer wall and the hot side outer wall is segmented by at least one gap; and
wherein at least one of a metal foil is arranged on an outer side of the at least one of the cold side outer wall and the hot side outer wall, and a jointing material is disposed in and closes the at least one gap.

9. A method of producing a heat-conducting and electrically insulating connection for a thermoelectric module, comprising:
forming an electrically insulating insulation layer, by applying a dielectric stoving paste having non-metallic solid particles onto an outer wall of the thermoelectric module and stoving the dielectric stoving paste, the outer wall segmented by at least one gap;
providing an electrically conductive metal layer, by applying a metallic stoving paste onto the insulation layer and stoving the metallic stoving paste; and
connecting at least one thermoelectric element to the metal layer by materially bonding the at least one thermoelectric element at least one of directly to the metal layer and indirectly via a separate conductor bridge to the metal layer, wherein said materially bonding is a sintering process or soldering process; and
closing the at least one gap of the outer wall, wherein closing the at least one gap includes at least one of arranging a metal foil on an outer side of the outer wall and disposing a jointing material in the at least one gap.

10. The method according to claim 9, further comprising coating the conductor bridge with at least one of a silver-based material and a nickel-based material.

11. The method according to claim 9, wherein the dieletric stoving paste includes a polymer-based system or a glass-based system.

12. The method according to claim 9, wherein the metallic stoving paste is a polymer-based system with metal particles or a glass-based system with metal particles.

13. The thermoelectric module according to claim 8, wherein the electrical insulation dielectric layer is a solidified dielectric stoving paste.

14. The thermoelectric module according to claim 8, wherein the electrically conductive metal layer is a solidified metallic stoving paste.

15. The thermoelectric module according to claim 8, wherein the electrical insulation dielectric layer has a layer thickness of at least 20 μm.

16. The thermoelectric module according to claim 8, wherein the electrically conductive metal layer has a layer thickness of at least 5 μm.

17. The thermoelectric module according to claim 8, wherein the electrically conductive metal layer is a polymer-based material with metal particles.

18. The thermoelectric module according to claim 8, wherein the electrically conductive metal layer is a glass-based layer with metal particles.

19. The thermoelectric module according to claim 8, wherein the at least one thermoelectric element has an element body of a thermoelectrically active material, and wherein a metal coating is disposed on the element body at least in a region of the at least one conductor bridge.

20. The thermoelectric module according to claim 8, wherein the at least one thermoelectric element is connected to at least one of the at least one conductor bridge and the electrically conductive metal layer via a materially bonded connection, the materially bonded connection including a silver sintered connection, a brazed connection or a soft soldered connection.
